(19) United States
(12) Patent Application Publication
(10) Pub. No.: US 2024/0079231 A1
(43) Pub. Date: Mar. 7, 2024

(54) METHOD AND DEVICE FOR DEPOSITING SILICON ONTO SUBSTRATES

(71) Applicant: ASM IP Holding B.V., Almere (NL)

(72) Inventors: John Tolle, Gilbert, AZ (US); Robert Vyne, Chandler, AZ (US)

(21) Appl. No.: 18/388,578

(22) Filed: Nov. 10, 2023

Related U.S. Application Data
(62) Division of application No. 17/509,290, filed on Oct. 25, 2021.
(60) Provisional application No. 63/106,789, filed on Oct. 28, 2020.

(51) Int. Cl. H01L 21/02; C23C 16/02; C23C 16/24; C23C 16/455; H01J 37/32

(52) U.S. Cl. CPC H01L 21/02532; C23C 16/0245; C23C 16/24; C23C 16/455; H01J 37/32449; H01J 37/32899; H01L 21/02576; H01L 21/02579; H01L 21/0262; H01J 37/32357; H01J 2237/332; H01J 2237/334

(57) ABSTRACT

A method for forming a layer on a substrate includes providing a substrate in a reactor of a semiconductor processing system, the reactor having a divider separating an upper chamber from a lower chamber and a substrate holder therein, the substrate having upper and lower surfaces. The wafer is positioned within the reactor using the substrate holder such that the upper surface bounds the upper chamber, a silicon-containing gas is flowed through the upper chamber to deposit a layer of the upper surface, and a halogen-containing gas is flowed through the lower chamber to etch a deposited film on at least one wall bounding the lower chamber while flowing the silicon-containing gas through the upper chamber. Semiconductor processing systems are also described.

### CROSS-REFERENCE TO RELATED APPLICATIONS

This application is a divisional of, and claims priority to and the benefit of, U.S. patent application Ser. No. 17/509,290, filed Oct. 25, 2021 and titled “METHOD AND DEVICE FOR DEPOSITING SILICON ONTO SUBSTRATES,” which is a nonprovisional of, and claims priority to and the benefit of, U.S. Provisional Patent Application No. 63/106,789, filed Oct. 28, 2020 and titled “METHOD AND DEVICE FOR DEPOSITING SILICON ONTO SUBSTRATES,” which are hereby incorporated by reference herein.

### FIELD OF THE INVENTION

The present disclosure generally relates to depositing silicon onto substrates using semiconductor processing systems. More particularly, the present disclosure relates to limiting deposition of silicon onto internal surfaces and structures in semiconductor processing systems while depositing silicon onto substrates in such devices.

### BACKGROUND OF THE DISCLOSURE

Silicon deposition techniques are commonly employed to deposit silicon onto wafers to fabricate semiconductor devices, such as power electronics and very large-scale integrated circuits. Silicon deposition may be accomplished in such techniques by flowing a silicon precursor through a reactor housing a wafer. Typically, the reactor maintains an environment conducive to silicon deposition such that silicon deposits on the wafer surface from the silicon precursor flowing through the reactor. Once a suitably thick silicon layer has deposited on the substrate surface, the wafer is unloaded from the reactor and sent on for further processing.

One challenge to such techniques is that silicon deposition on the wafer surface is typically accompanied by silicon deposition on other surfaces and structures within the reactor. For example, in some reactors, silicon films may develop on interior surfaces and/or movable parts located within the reactor, such as on the reactor walls and/or on movable structures employed to load and unload the wafer. These collateral silicon depositions may reduce reliability of the process tool, for example by reducing the transmissivity of the reactor walls (and thereby limiting the ability to communicate heat through the reactor walls from externally-positioned heat sources) and/or by creating interferences between movable structures and neighboring structure within the reactor. Silicon nodules may also (or alternatively) develop between the backside of the wafer and the chuck employed to support the wafer during deposition. Such silicon nodules may fix the wafer to the chuck, potentially leading to substrate damage during wafer unloading and/or during subsequent processing of the wafer. Silicon film and nodule development may be particularly problematic in deposition operations employed to deposit relatively thick silicon layers.

Various countermeasures exist for the tendency of silicon nodules and/or silicon films within reactors during deposition operations. For example, some silicon deposition operations may include a preceding and/or a follow-on cleaning event to remove silicon films developed within the reactor during prior deposition operation(s). Scheduled maintenance may also be employed to periodically remove silicon film from within the reactor, such as through reactor disassembly to provide access to interior surfaces and structures otherwise inaccessible for silicon film removal. And in some techniques, the deposition operation itself may be divided into two or more deposition events, allowing the reactor to be cleaned between deposition events. This limits size of silicon nodules formed between the wafer and chuck during the deposition operation, limiting the tendency of nodules to fix the wafer to the chuck and/or cause damage to the wafer.

Such methods and devices have generally been considered suitable for their intended purpose. However, there remains a need in the art for improved methods for depositing silicon layers onto substrates and semiconductor processing systems. The present disclosure provides a solution to one or more of these needs.

### SUMMARY OF THE DISCLOSURE

A method for forming a silicon layer on a substrate is provided. The method includes providing a substrate in a reactor of a semiconductor processing system, the reactor containing a substrate holder and a divider separating an upper chamber from a lower chamber, the substrate having an upper surface and a lower surface opposite the upper surface. The substrate is positioned within the upper chamber of the reactor using the substrate, and a silicon-containing gas is flowed through the upper chamber to deposit a layer of the upper surface of the substrate. A halogen-containing gas is flowed through the lower chamber to etch a deposited film on at least one wall bounding the lower chamber of the reactor while flowing the silicon-containing gas through the upper chamber of the reactor. The upper surface of the substrate etched with the halogen-containing gas to control thickness of the silicon layer at a periphery of the upper surface of the substrate.

In certain examples, the method may include etching the lower surface of the substrate with the halogen-containing gas to limit deposition of silicon on the lower surface of the substrate.

In certain examples, the method may include flowing the halogen-containing gas into the upper chamber through a gap defined between the substrate and the divider separating the upper chamber from the lower chamber of the reactor.

In certain examples, the method may include tuning edge thickness of the silicon layer at the peripheral portion of the upper surface of the substrate to a target profile. Tuning may be accomplished, for example, by adjusting mass flow of the halogen-containing gas through the lower chamber of the reactor.

In certain examples, the method may include flowing a purge gas through the lower chamber of the reactor, the halogen-containing gas intermixed with the purge gas.

In certain examples, the method may include flowing a carrier gas including the halogen-containing gas through the upper chamber of the reactor.

In certain examples, the method may include activating the halogen-containing gas prior to flowing the halogen-containing gas through the lower chamber of the reactor.

In certain examples, the method may include flowing a dopant-containing gas through the upper chamber of the reactor while flowing the halogen-containing gas through the lower chamber of the reactor.

In certain examples, the method may include selecting the halogen-containing gas to include least one of hydrogen chloride (HCl); chlorine (Cl₂); and fluorine (F₂).

In certain examples, the method may include selecting the silicon-containing gas to include at least one of silane (SiH₄); disilane (Si₂H₆); trisilane (Si₃H₈); and tetrasilane (Si₄H₁₀).

In certain examples, the method may include selecting a carrier gas to include at least one of nitrogen (N₂), hydrogen (H₂), helium (He), argon (Ar), and any other noble gas; the method further including flowing the silicon-containing gas and the carrier gas through the upper chamber of the reactor.

In certain examples, the method may further include selecting a dopant-containing gas including at least one of diborane (B₂H₆); phosphine (PH₃); and arsine (AsH₃), the method further including flowing the silicon-containing gas and the dopant-containing gas through the upper chamber of the reactor.

In certain examples, the method may include maintaining the reactor at a temperature that is between about 300° C. and about 750° C. or between about 550° C. and about 750° C. while flowing the halogen-containing gas through the lower chamber of the reactor.

In certain examples, the method may include maintaining a pressure of between about 10 Torr and about 900 Torr within the reactor while flowing the halogen-containing gas through the lower chamber of the reactor.

In certain examples, the method may include flowing the halogen-containing gas through the lower the lower chamber for a duration substantially equivalent to a duration of flowing the silicon-containing gas through the upper chamber of the reactor.

In certain examples, the method may include flowing the halogen-containing gas through the lower chamber of the reactor for between about 2 minutes and about 25 minutes.

A semiconductor processing system is also provided. The system includes a reactor having an upper chamber and a lower chamber. The reactor is configured to support therein a substrate with an upper surface and a lower surface opposite the upper surface. A silicon-containing gas source is connected to the upper chamber of the reactor and is configured to provide a silicon-containing gas to the reactor. A halogen-containing gas source is connected to the lower chamber of the reactor and is configured to provide a halogen-containing gas to the reactor. A controller is operatively connected to the silicon-containing gas source and the halogen-containing gas source. The controller is responsive to instructions recorded on a memory to position the substrate within the upper chamber of the reactor using the substrate holder, flow a silicon-containing gas from the silicon-containing gas source through the upper chamber reactor to deposit a layer of the upper surface of the substrate, the flow a halogen-containing gas from the halogen-containing gas source through the lower chamber to etch a deposited film from at least one wall bounding the lower chamber of the reactor while flowing the silicon-containing gas through the upper chamber of the reactor. The instructions further cause the controller to flow the halogen-containing gas through the lower chamber of the reactor to etch the upper surface of the substrate with the halogen-containing gas to control edge thickness of a silicon layer deposited onto the surface of the substrate.

In certain examples, the halogen gas source may be independently connected to the upper chamber and the lower chamber of the reactor.

In certain examples, the semiconductor device may include a first mass flow controller (MFC) and a second MFC. The first MFC may connect the halogen-containing gas source to the upper chamber of the reactor. The second MFC may connect the halogen-containing gas source to the lower chamber of the reactor.

In certain examples, the semiconductor device may include a purge gas source connected to the lower chamber of the reactor to flow a purge gas flow to the lower chamber with the halogen-containing gas flowed through the lower chamber of the reactor.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system with a reactor constructed in accordance with the present disclosure, showing a halogen-containing gas source connected to a lower chamber of the reactor and a silicon-containing gas source connected to the upper chamber of the reactor;

FIG. 2 is a schematic view of the semiconductor processing system of FIG. 1, showing a substrate being provided into the reactor for deposition of a silicon layer onto an upper surface of the substrate;

FIG. 3 is a schematic view of the semiconductor processing system of FIG. 1, showing the substrate being positioned within the upper chamber of the reactor using a substrate holder;

FIG. 4 is a schematic view of the semiconductor processing system of FIG. 1, showing the halogen-containing gas source flowing a halogen-containing gas through the lower chamber of the reactor while the silicon-containing gas source flows a silicon-containing gas through the upper chamber of the reactor;

FIG. 5 is a schematic view of a portion of the semiconductor processing system of FIG. 1 including the reactor, showing the halogen-containing gas etching a deposited film from at least one wall bounding the lower chamber of the reactor, the lower surface of the substrate, and a periphery of the silicon layer being deposited onto the upper surface of the substrate;

FIG. 6 is a schematic view of the semiconductor processing system of FIG. 1, showing the substrate being unloaded from the reactor subsequent to the halogen-containing gas being flowed through the lower chamber of the reactor;

FIG. 7 is a schematic view of the semiconductor processing system of FIG. 1 according to an example, showing a remote plasma unit activating the halogen-containing gas prior to halogen-containing gas being flowed through the lower chamber of the reactor;

FIG. 8 is a schematic view of the semiconductor processing system of FIG. 1 according to another example, showing the halogen-containing gas flowing through the upper chamber of the reactor as a carrier gas for the silicon-containing gas while the halogen-containing gas is flowed through the lower chamber of the reactor;

FIG. 9 is a schematic view of the semiconductor processing system of FIG. 1 according to another example, showing a controller operatively connected to the silicon-containing gas source and the halogen-containing gas source to flow the halogen-containing through the lower chamber of the reactor while the silicon-containing gas flows through the upper chamber of the reactor; and

FIG. 10 is a block diagram of a method for forming a silicon layer on a substrate using a semiconductor processing system, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

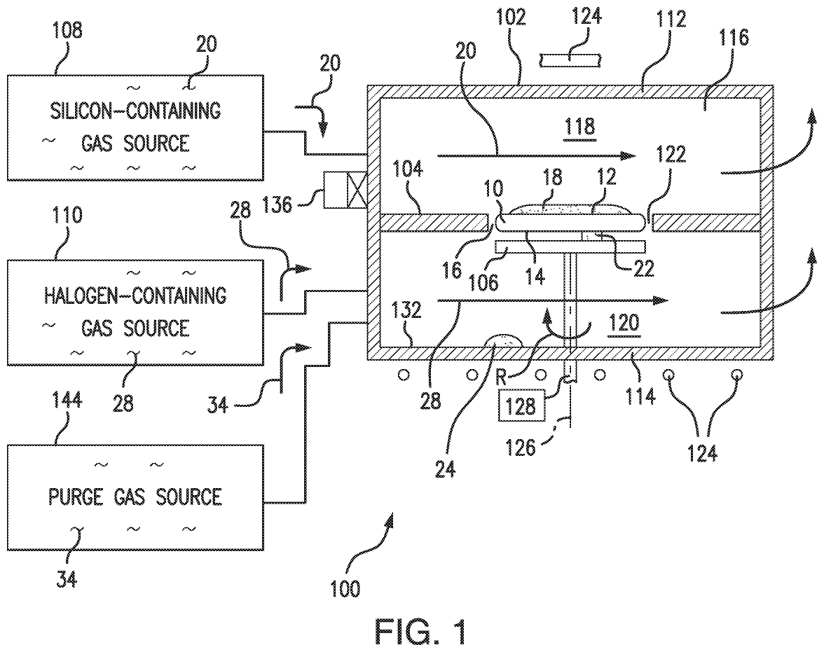

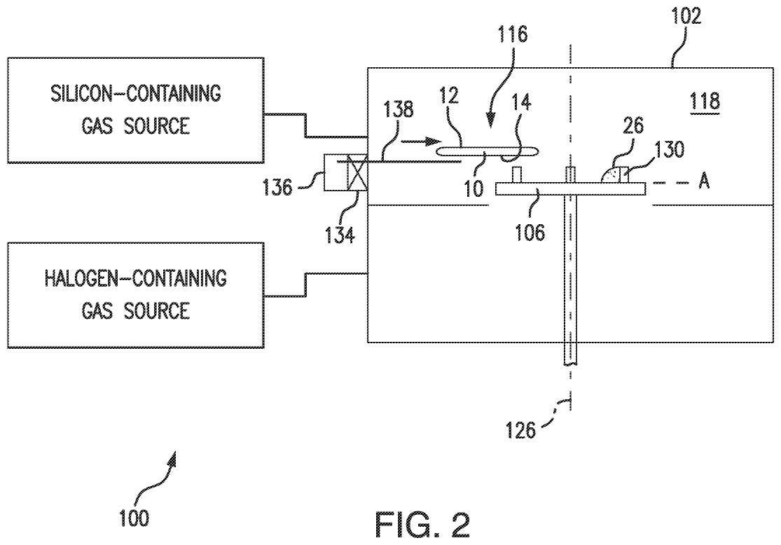

Reference will now be made to the drawings wherein like reference numerals identify similar structural features or aspects of the subject disclosure. For purposes of explanation and illustration, and not limitation, a partial view of an example of a semiconductor processing system in accordance with the disclosure is shown in FIG. 1 and is designated generally by reference character 100. Other embodiments of semiconductor processing systems and methods for forming silicon layers on substrates in accordance with the present disclosure, or aspects thereof, are provided in FIGS. 2-10, as will be described. The devices and methods described herein may be used deposit silicon layers onto substrates, such as silicon wafers, for the fabrication of very large scale integrated (VLSI) circuits using low pressure chemical vapor deposition (CVD) or epitaxial techniques. However, the present disclosure is not limited to low pressure CVD techniques, VLSI circuits, or to epitaxy in general.

Referring to FIG. 1, the semiconductor processing system 100 is shown. The semiconductor processing system 100 may include a reactor 102, a divider 104, and a substrate holder 106. The semiconductor processing system 100 may also include a silicon-containing gas source 108, a halogen-containing gas source 110, a purge gas source 144, and a substrate handler 136. In the illustrated example the semiconductor processing system 100 is a chemical vapor deposition (CVD) semiconductor processing system, such as an atmospheric pressure CVD device. However, as will be appreciated by those of skill in the art, low pressure CVD devices, high pressure CVD devices, and atomic layer deposition devices may also benefit from the present disclosure.

The reactor 102 is formed from a transmissive material 114, e.g., a ceramic material like quartz, and has a hollow interior 116 containing the divider 104. The divider 104 is fixed within the interior 116 of the reactor 102, divides the interior 116 into an upper chamber 118 and a lower chamber 120, and defines therethrough a divider aperture 122. The divider aperture 122 connects the lower chamber 120 to the upper chamber 118, the divider aperture 122 providing fluid communication between the upper chamber 118 and the lower chamber 120. One or more lamps (or lamp arrays) 124 may be positioned outside of the reactor 102 for communicating thermal energy into the reactor 102 through the transmissive material 114 forming the reactor 102.

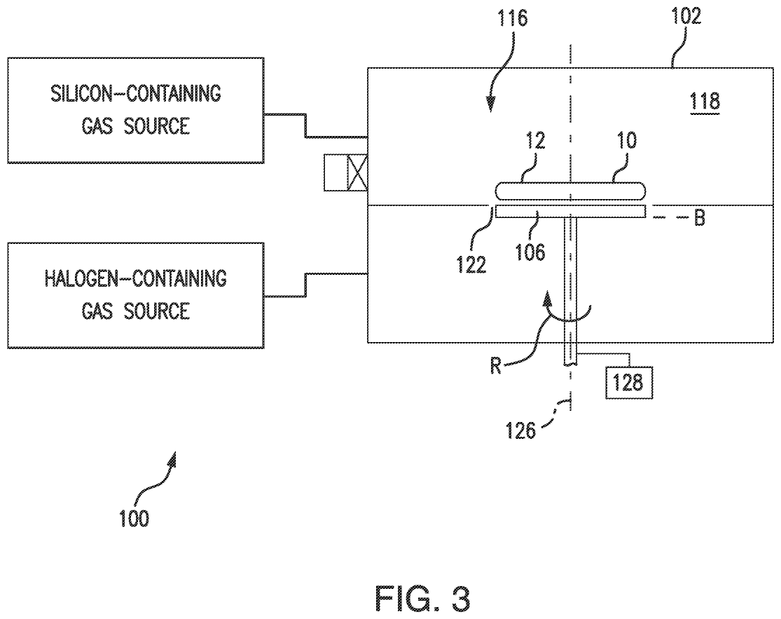

The substrate holder 106 is supported within the interior 116 of the reactor 102 and is configured to hold a substrate 10. The substrate holder 106 is operably associated with a substrate holder drive 128. The substrate holder drive 128 may be configured to displace the substrate holder 106 between a first position A (shown in FIG. 2) and a second position B (shown in FIG. 3) along the rotation axis 126 for loading the substrate 10 into the reactor 102, positioning the substrate 10 for deposition of silicon onto the substrate 10, and unloading the substrate 10 from the reactor 102. The substrate holder drive 128 may also configured to rotate R the substrate holder 106 about the rotation axis 126 during deposition of silicon onto the substrate 10. In certain examples one or more lifter pins 130 (shown in FIG. 2) may be movably supported by the substrate holder 106 to seat and unseat the substrate 10 from the substrate holder 106. The reactor 102 may be as shown and described in U.S. Pat. No. 7,462,239 to Brabant et al., issued on Dec. 9, 2009, the contents of which are incorporated herein by reference in its entirety.

The substrate 10 has an upper surface 12, an opposite lower surface 14, and an edge or bevel 16. The edge or bevel 16 of the substrate 10 couples the upper surface 12 of the substrate 10 with the lower surface 14 of the substrate 10. It is contemplated that, when loaded on the substrate holder 106, the upper surface 12 of the substrate 10 be disposed along the rotation axis 126 at a location axially overlapping the substrate holder 106, the lower surface 14 of the substrate 10 be disposed along the rotation axis 126 at a location between the upper surface 12 and the substrate holder 106, and the edge or bevel 16 of the substrate 10 extend about the rotation axis 126 for deposition of a silicon layer 18 on the upper surface 12 of the substrate 10. In certain examples, the substrate 10 is a silicon wafer. In accordance with certain examples the substrate 10 may include at least a portion of the power electronics device or a VLSI circuit formed thereon.

The purge gas source 144 may be connected to the reactor 102, may include a purge gas 34, and may be configured flow the purge gas 34 through the lower chamber 120 of the reactor 102 intermixed with the halogen-containing gas 28. The purge gas 34 may include, for example, nitrogen (N₂) or Argon (Ar).

The silicon-containing gas source 108 is connected to the reactor 102 and includes a silicon-containing gas 20. The silicon-containing gas source 108 may be connected to the reactor 102 and configured to provide a flow of the silicon-containing gas 20 to the reactor 102. The reactor 102 may be configured to flow the silicon-containing gas 20 received from the silicon-containing gas source 108 through the upper chamber 118 of the reactor 102. The reactor 102 may further be configured to maintain an environment suitable for deposition of the silicon layer 18 onto the upper surface 12 of the substrate 10. The silicon layer 18 may be deposited using an epitaxial technique, such as shown and described in U.S. Pat. No. 10,446,393 to Bhargava et al., issued on Oct. 15, 2019, the contents of which are incorporated herein by reference in its entirety. The silicon-containing gas 20 may include, for example, silane (SiH₄), disilane (Si₂H₆), trisilane (Si₃H₈), or tetrasilane (Si₄H₁₀).

As has been discussed above, flowing the silicon-containing gas 20 through the upper chamber 118 of the reactor 102 may cause silicon nodules to form within the reactor employed for deposition. For example, as shown in FIG. 1, a silicon nodule 22 may form between on the lower surface 14 of the substrate 10 and the substrate holder 106. Such silicon nodules may lead to damage of the substrate 10 during unloading of the substrate 10 from the reactor 102. Such silicon nodules may also lead the damage of the substrate 10 at subsequent processing operations of the substrate 10.

As has also been discussed above, flowing the silicon-containing gas 20 through the upper chamber 118 may (alternatively or additionally) cause a silicon film 24 to form onto walls 132 bounding the lower chamber 120 of the reactor 102. A silicon film 26 (shown in FIG. 2) may also form on a surface of the one or more lifter pin 130 movable supported by the substrate holder 106. Such silicon films may potentially reduce reliability of the semiconductor processing system 100, e.g., by limiting transmissivity of the walls 132 and/or by creating interferences between the one or more lifter pin 130 and the substrate holder 106.

To limit the risk of damage to the substrate 10 and/or reliability liability posed by such silicon nodules and/or silicon films to the silicon processing system 100, the semiconductor processing system 100 includes the halogen-containing gas source 110. The halogen-containing gas source 110 is connected to the reactor 102 and includes a halogen-containing gas 28. It is contemplated that the halogen-containing gas source 110 be connected to the lower chamber 120 of the reactor 102 and configured to provide the halogen-containing gas 28 to the reactor 102. The reactor 102 in turn is configured to flow the halogen-containing gas 28 through the lower chamber 118 of the reactor 102 to etch a deposited film on at least one internal surface and/or structure within the reactor 102 while the reactor 102 flows the silicon-containing gas 20 through the upper chamber 118. The halogen-containing gas 28 may include, for example, hydrochloric acid or hydrogen chloride (HCl), chlorine (Cl₂), or fluorine (F₂).

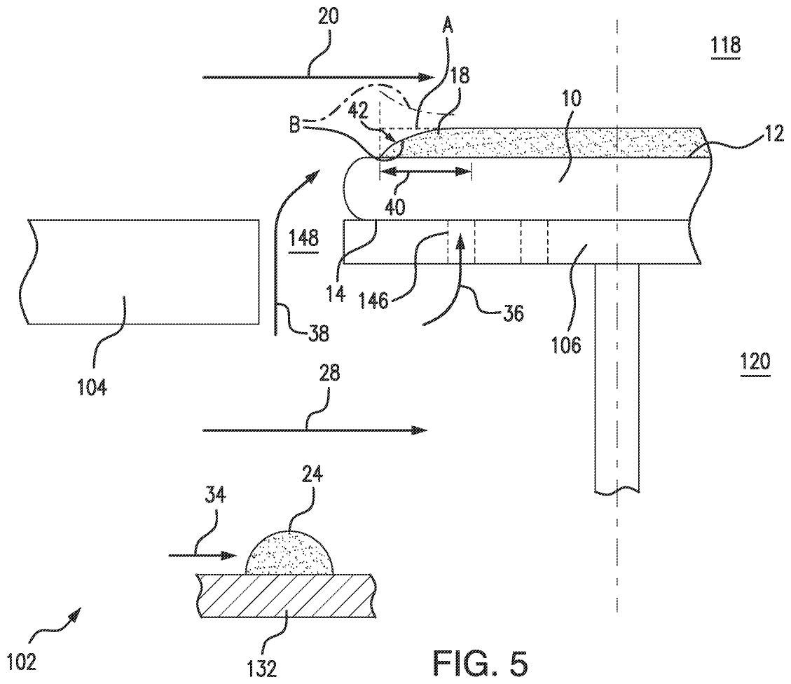

In certain examples the flow of the halogen-containing gas 28 etches a deposited film on at least one of the walls 132 bounding the lower chamber 120, limiting (or eliminating entirely) deposition of film on at least one of the walls 132, such as the silicon film 24. In accordance with certain examples, the flow of the halogen-containing gas 28 (alternatively or additionally) may etch silicon on the lower surface 14 of the substrate 10, limiting (or eliminating entirely) the formation of silicon nodules, such as the silicon nodule 22, between the substrate 10 and the substrate holder 106. It is also contemplated that, in accordance with certain examples, the flow of the halogen-containing gas 28 may etch a peripheral portion 40 (shown in FIG. 5) of the silicon layer 18 during deposition of the silicon layer 18 onto the upper surface 12 of the substrate 10, e.g., to tune a thickness profile 42 (shown in FIG. 5) of the silicon layer 18 at the peripheral portion 40 of the silicon layer 18.

With reference to FIGS. 2-6, the semiconductor processing system 100 is shown forming the silicon layer 18 (shown in FIG. 1) onto the upper surface 12 of the substrate 10. As shown in FIG. 2, the substrate 10 is first provided in the reactor 102 for deposition of the silicon layer 18 onto the upper surface 12 of the substrate 10. Specifically, the substrate holder 106 first translates along the rotation axis 126 to the first position A, e.g., a load/unload position. Next, a gate valve 134 connecting the reactor 102 to the external environment opens to provide the substrate handler 136 access to the interior 116 of the reactor 102. The substrate handler 136 extends an arm/end effector 138 supporting the substrate 10 through the gate valve 134, across the upper chamber 118, and registers the substrate 10 over the substrate holder 106.

Once the substrate 10 is registered with the substrate holder 106, the one or more lifter pins 130 then deploy from the substrate holder 106. As the one or more lifter pins 130 deploy from the face of the substrate holder 106, the one or more lifter pins 130 contact the lower surface 14 of the substrate 10, transferring the substrate 10 from the arm/end effector 138 to the one or more lifter pins 130. Once the substrate 10 is transferred the substrate handler 136 withdraws the arm/end effector 138 from the interior 116 of the reactor 102 through the gate valve 134. The gate valve 134 thereafter closes, isolating the interior 116 of the reactor 102 from the external environment.

As shown in FIG. 3, the substrate 10 is next positioned within the reactor 102 for deposition of the silicon layer 18 (shown in FIG. 1). Specifically, the one or more lifter pins 130 (shown in FIG. 2) withdraw into the substrate holder 106 to seat the substrate 10 against the substrate holder 106. The substrate holder 106 may thereafter displaces along the rotation axis 126 from the first position A (shown in FIG. 2) to the second position B, e.g., a deposition position. In the second position B, the substrate 10 is positioned within the upper chamber 118 of the reactor 102 and the substrate holder 106 is itself disposed at least partially within the divider aperture 122. Next, the substrate holder drive 128 rotates R the substrate holder 106 (and the substrate 10) about the rotation axis 126, and temperature and pressure within the interior 116 of the reactor 102 conditioned for deposition of the silicon layer 18 (shown in FIG. 1) onto the upper surface 12 of the substrate 10.

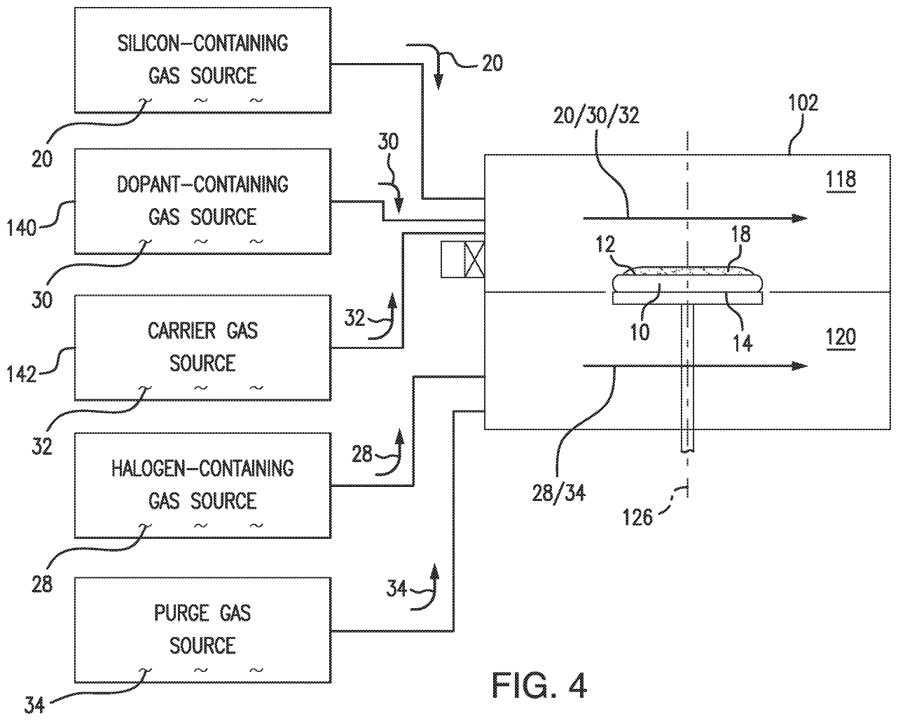

As shown in FIG. 4, the silicon-containing gas source 108 next provides the silicon containing gas 20 to the reactor 102. The silicon-containing gas 20 flows through the upper chamber 118 of the reactor 102. As the silicon-containing gas 20 flows through the upper chamber 118 the silicon layer 18 deposits onto the upper surface 12 of the substrate 10.

While the silicon-containing gas 20 flows through the reactor 102, and the silicon layer 18 deposits on the upper surface 12 of the substrate 10, the halogen-containing gas source 110 provides the halogen-containing gas 28 to the reactor 102. The reactor 102 flows the halogen-containing gas 28 through the lower chamber 120 of the reactor 102. As the halogen-containing gas 28 flows through the lower chamber 120 of the reactor 102 the halogen-containing gas 28 etches film deposited film on at least one of (a) the walls 132 (shown in FIG. 1) bounding the lower chamber 120 of the reactor 102, (b) the lower surface 14 of the substrate 10, (c) and/or the peripheral portion 40 (shown in FIG. 5) of the silicon layer 18, as the silicon layer 18 deposits onto the upper surface 12 of the substrate 10.

In certain examples, the halogen-containing gas 28 and the silicon-containing gas 20 are flowed through the upper chamber 118 and the lower chamber 120, respectively, at the same time with one another. This may improve throughput of the semiconductor processing system 100, for example, by limiting (or eliminating entirely) the need to etch a deposited film on at least one of the walls 132 bounding the lower chamber 120 of the reactor 102 between deposition events. In accordance with certain examples, the halogen-containing gas 28 may start flowing through the lower chamber 120 prior to start of the flow of silicon-containing gas 20 through the upper chamber 118 or start subsequent to start of the flow of the silicon-containing gas 20 through the upper chamber 118 of the reactor 102. It is also contemplated that, in accordance with certain examples, the halogen-containing gas 28 may cease flowing through the lower chamber 120 prior to termination of the flow of the silicon-containing gas 20 through the upper chamber 118, or subsequent to termination of the flow of the silicon containing gas 20 through the upper chamber 118 of the reactor 102.

In certain examples, the semiconductor processing system 100 may include a dopant gas source 140. In such examples the dopant gas source 140 may be connected to the reactor 102 and may be configured to flow a dopant gas 30 through the upper chamber 118 with the silicon-containing gas 20 for doping the silicon layer 18 deposited on the upper surface 12 of the substrate 10. The dopant gas 30 may include, for example, diborane (B₂H₆), phosphine (PH₃), or arsine (AsH₃).

In accordance with certain examples, the semiconductor processing system 100 may include a carrier gas source 142. In such examples the carrier gas source 142 may be connected to the reactor 102 and may be configured to flow a carrier gas 32 through the upper chamber 118 to carry the silicon-containing gas 20 and/or the dopant gas 30 through the upper chamber 118 of the reactor 102. The dopant gas 30 may include, for example, diborane (B₂H₆), phosphine (PH₃), or arsine (AsH₃).

It is contemplated that the reactor 102 may be configured to maintain a temperature of between about 300° C. and about 750° C. or between about 550° C. and about 1220° C. within the reactor 102 while flowing the halogen-containing gas 28 through the lower chamber 120 of the reactor 102. More specifically, the reactor 102 may be configured to maintain a temperature of between about 300° C. and about 750° C. or between about 550° C. and about 1220° C. within the reactor 102 while flowing the halogen-containing gas 28 through the lower chamber 120 within the upper chamber 118 of the reactor 102 and flowing the halogen-containing gas 28 through the lower chamber 120 of the reactor 102.

It is also contemplated that the reactor 102 may be configured to maintain a pressure of between about 10 Torr and about 800 Torr within the reactor 102 while flowing the halogen-containing gas 28 through the lower chamber 118 of the reactor 102. More specifically, the reactor 102 may be configured to maintain a pressure of between about 10 Torr and about 800 Torr within the upper chamber 118 of the reactor while flowing the halogen-containing gas 28 through the lower chamber 120 of the reactor 102.

It is further contemplated that, in accordance with certain examples, the reactor 102 may be configured to flow the halogen-containing gas 28 through the lower chamber 120 for between about 2 minutes and about 25 minutes while flowing the silicon-containing gas 20 through the upper chamber 118. In certain examples, the reactor 102 may be configured to flow the halogen-containing gas 28 through the lower chamber 120 for between approximately 35 seconds and approximately 65 seconds while flowing the silicon-containing gas 20 through the upper chamber 118 of the reactor 102.

As shown in FIG. 5, flowing the halogen-containing gas 28 through the lower chamber 120 while the silicon-containing gas 20 flows through the upper chamber 118 of the reactor 102 enables etching a deposited film on at least on surface and/or features located within the reactor 102. For example, as shown with a flow arrow 34, the halogen-containing gas 28 may etch a deposited film on at least one of the walls 132 bounding the lower chamber 120 of the reactor 102, e.g., the silicon film 24. Further, as shown with the flow arrow 36, the halogen-containing gas 28 may also (or alternatively) etch silicon on the lower surface 14 of the substrate 10, e.g., the silicon nodule 22 (shown in FIG. 1) thereon. Etching silicon of the lower surface 14 of the substrate 10 may be accomplished, for example, through an aperture 146 extending through the substrate holder 106 and fluidly coupling the lower chamber 120 of the reactor 102 with the lower surface 14 of the substrate 10.

In certain examples, the flow of the halogen-containing gas 28 through the lower chamber 120 may be employed to etch the silicon layer 18 as the silicon layer 18 is deposited on the upper surface 12 of the substrate 10. Specifically, as shown with a flow arrow 38, it is contemplated a portion of the halogen-containing gas 28 flowing through the lower chamber 120 may flow through a gap 148 defined between the substrate holder 106 and the divider 104, and into the upper chamber 118. Once in the upper chamber 118, the halogen-containing gas 28 slows the deposition of silicon within a peripheral portion 40 of the silicon layer 18, reducing thickness of the silicon layer 18 within the peripheral portion 40 relative to a nominal thickness of the silicon layer 18 otherwise deposited within the peripheral portion 40 of the silicon layer 18.

It is also contemplated that the flow of the halogen-containing gas 28 flowing through the lower chamber 120 may be employed to tune thickness of the silicon layer 18 within the peripheral portion 40 of the silicon layer 18. For example, the halogen-containing gas 28 may make thickness of the silicon layer 18 within the peripheral portion 40 more uniform than otherwise formed by the silicon-containing gas 20 flowing through the upper chamber 118 of the reactor 102, as shown in FIG. 5 with reference letter at A. Alternatively, the halogen-containing gas 28 may make the thickness of the silicon layer 18 within the peripheral portion 40 more concave or convex than otherwise formed by the silicon-containing gas 20 flowing through the upper chamber 118 of the reactor 102, as shown in FIG. 5 with reference letter B.

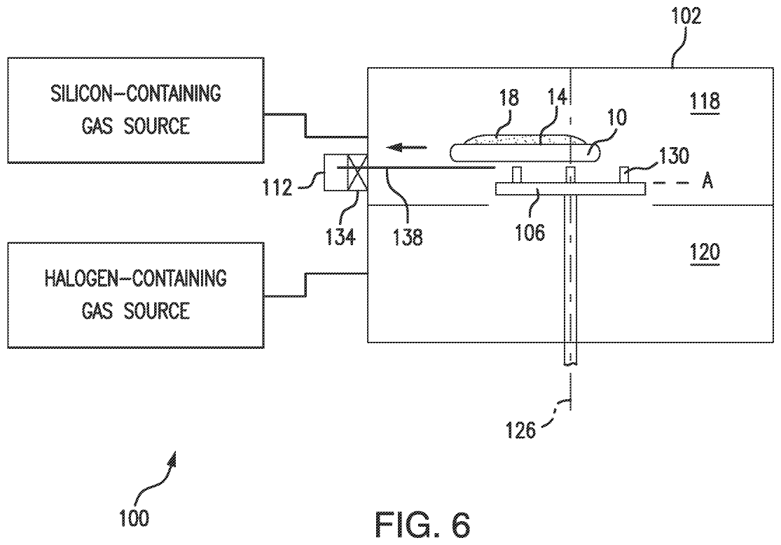

As shown in FIG. 6, once the silicon layer 18 is deposited on the upper surface 14 of the substrate 10, the substrate 10 is unloaded from the reactor 102. Unloading may be accomplished by first ceasing (a) the flow of the silicon-containing gas 20 (shown in FIG. 1) to the upper chamber 118 of the reactor 102, and (b) the flow of the halogen-containing gas 28 (shown in FIG. 1) to the lower chamber 120 of the reactor 102. Rotation R (shown in FIG. 1) of the substrate holder 106 about the rotation axis 126 may cease. The substrate holder 106 may be translated from the second position B (shown in FIG. 3) to the first position A, the one or more lifter pin 130 may deployed from the substrate handler 136 to displace the substrate 10 from the substrate holder 106.

Movement of the one or more lifter pins 130 may displace the substrate 10 from the upper surface 12 of the substrate holder 106. The gate valve 134 may open, the substrate handler 136 extend the arm/end effector 138 into the upper chamber 118 of the reactor 102, and the arm/end effector 138 may be inserted between the substrate 10 and the substrate holder 106. The one or more lifter pins 130 may then retract to transfer the substrate 10 to the arm/end effector 138, and the arm/end effector 138 with the substrate 10 may then be retracted from the reactor 102. The reactor 102 may thereafter be employed is a subsequent deposition operation by loading another substrate into the reactor 102.

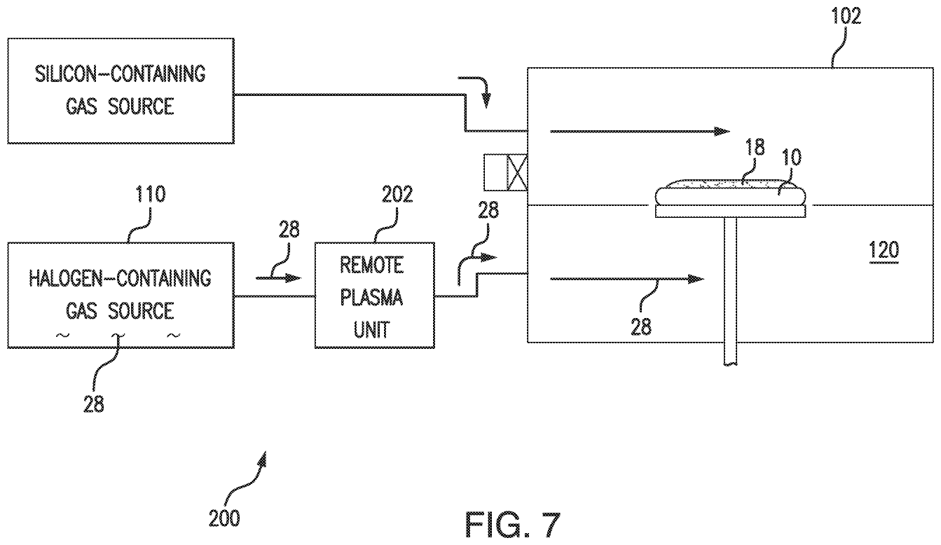

With reference to FIG. 7, a semiconductor processing system 200 is shown. The semiconductor processing system 200 is similar to the semiconductor processing system 100 (shown in FIG. 1) and additionally includes a remote plasma unit 202. The remote plasma unit 202 connects the halogen-containing gas source 110 to the lower chamber 120 of the reactor 102 and may be configured to activate the halogen-containing gas 28. As will be appreciated by those of skill in the art, the connection of the remote plasma unit 202 to the lower chamber 120 allows for etching a deposited film on one or more of the walls 132 bounding the lower chamber 120 of the reactor 102 using an activated halogen-containing gas, e.g., fluorine (F₂). Such gases enable the silicon layer 18 to be deposited at a relatively low temperature, allowing the substrate 10 to include materials intolerant of relatively high deposition temperatures.

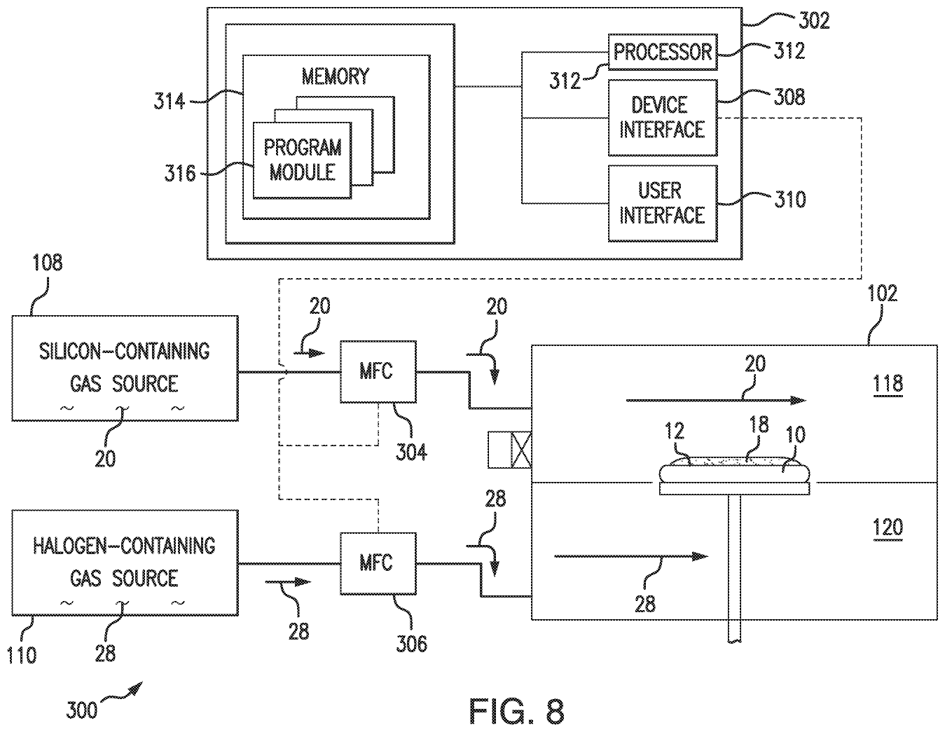

With reference to FIG. 8, a semiconductor processing system 300 is shown. The semiconductor processing system 300 is similar to the semiconductor processing system 100 (shown in FIG. 1) and additionally includes a controller 302, a silicon-containing gas mass flow controller (MFC), 304, and a halogen-containing gas MFC 306. The controller 302 is operably connected to semiconductor processing system 300 to flow the halogen-containing gas 28 through the lower chamber 120 while the silicon-containing gas 20 flows through the upper chamber 118 of the reactor 102.

In the illustrated example, the controller 302 is operably connected to the semiconductor processing system 300 via the silicon-containing gas MFC 304 and the halogen-containing gas MFC 306. The halogen-containing gas MFC 306 in turn connects the halogen-containing gas source 110 to the lower chamber 120 of the reactor 102 to flow the halogen-containing gas 28 through the lower chamber 120 of the reactor 102. The silicon-containing gas MFC 304 further connects the silicon-containing gas source 108 to the upper chamber 118 of the reactor 102 to flow the silicon-containing gas 20 through the upper chamber 118 of the reactor 102. Either (or both) the halogen-containing gas MFC 304 and the silicon-containing gas MFC 306 may include, for example, a metering valve for metering gas flowing therethrough.

The controller 302 includes a device interface 308, a user interface 310, a processor 312, and a memory 314. The device interface 308 connects the controller 302 to the semiconductor processing system 300, e.g., through one or more of the halogen-containing gas MFC 304, the silicon-containing gas MFC 306, the substrate holder drive 128 (shown in FIG. 1), and the substrate handler 136 (shown in FIG. 1). The user interface 310 is configured to display output to a user and/or receive input from a user, e.g., recipe selection. The processor 312 is operably connected to the user interface 310 and is disposed in communication with the semiconductor processing system 300 through the device interface 308. The processor 312 is also disposed in communication with the memory 314.

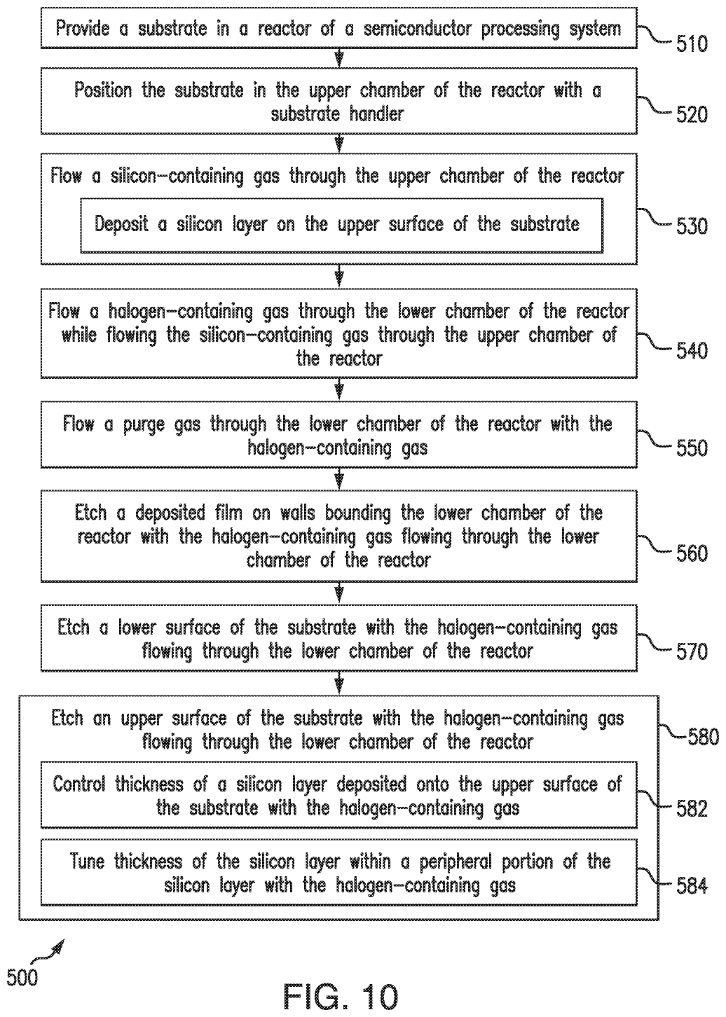

The memory 314 includes a non-transitory machine-readable medium having a plurality of program modules 316 recorded on the memory 314. The program modules 316 have instructions recorded therein that, when read by the processor 312, cause the processor 312 to execute certain operations, the controller 302 thereby responsive to the instructions recorded thereon. Among the operations are operations for a method 500 (shown in FIG. 10) for depositing silicon onto a substrate, e.g., for depositing the silicon layer 18 onto the upper surface 12 of the substrate 10.

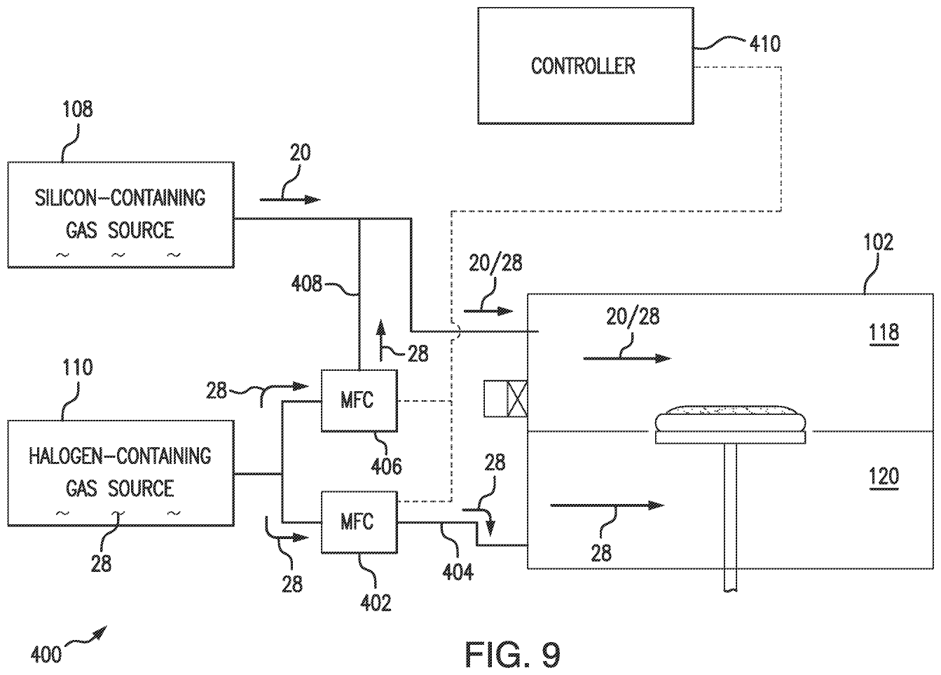

With reference to FIG. 9, a semiconductor processing system 400 is shown. The semiconductor processing system 400 is similar to the semiconductor processing system 100 (shown in FIG. 1) and is configured to provide independent flows of the halogen-containing gas 28 to both the upper chamber 118 of the reactor 102, e.g., a lower chamber halogen-containing gas flow and an upper chamber halogen-containing gas flow. The independent flows enable the halogen-containing gas 28 to be provided to the lower chamber 120 as a lower chamber halogen-containing gas flow to etch a deposited film on at least one internal surface and/or structure within the reactor 102 while the halogen-containing gas 28 is further provided to the upper chamber 118 to serve as a carrier gas for the silicon-containing gas 20.

In the illustrated example, the independent halogen-containing gas flows are provided to the semiconductor processing system 400 by a first halogen-containing gas mass flow controller (MFC) 402, a first halogen-containing gas conduit 404, a second halogen-containing gas MFC 406, and a second halogen-containing gas conduit 408. The first halogen-containing gas MFC 402 connects the halogen-containing gas source 110 to the lower chamber 120 of the reactor 102 through the first halogen-containing gas conduit 404. The second halogen-containing gas MFC 406 connects the halogen-containing gas source 110 to the upper chamber 118 of the reactor 102 through the second halogen-containing gas conduit 408.

In certain examples, the first halogen-containing gas MFC 402 and the second halogen-containing gas MFC 406 are operably associated with a controller 410 to provide the upper chamber halogen-containing gas flow to the upper chamber 118 and the lower chamber halogen-containing gas flow to the lower chamber 120 of the reactor 102. As will be appreciated by those of skill of art in view of the present disclosure, other arrangements may be employed to provide independent flows of the halogen-containing gas 28 to the lower chamber 120 and the upper chamber 118 and remain within the scope of the present disclosure.

With reference to FIG. 10, the method 500 for forming a silicon layer on a substrate is shown. As shown with box 510, a substrate is provided in a reactor of a semiconductor processing system, e.g., the substrate 10 (shown in FIG. 1) provided in the reactor 102 (shown in FIG. 1) of the semiconductor processing system 100 (shown in FIG. 1). The substrate is then positioned within the reactor using a substrate holder, e.g., the substrate holder 106 (shown in FIG. 1), as shown with box 520. It is contemplated that the substrate may be positioned within the upper chamber of the reactor, e.g., such that the substrate 10 (shown in FIG. 1) is in the upper chamber 118 (shown in FIG. 1) of the reactor 102 (shown in FIG. 1).

Once the substrate is positioned within the reactor, a silicon-containing gas, e.g., the silicon-containing gas 20 (shown in FIG. 1), is flowed through the upper chamber of the reactor to deposit a layer of the upper surface of the substrate, as shown with box 530. The silicon-containing gas causes a silicon layer, e.g., the silicon layer 18 (shown in FIG. 1), to be deposited onto the upper surface of the substrate, as shown with box 532. While the silicon-containing gas flows through the upper chamber of the reactor, a halogen-containing gas is flowed through a lower chamber of the reactor, e.g., the halogen-containing gas 28 (shown in FIG. 1) through the lower chamber 120 (shown in FIG. 1) of the reactor 102, while the silicon-containing gas flows through the upper chamber of the reactor, as shown with box 540. In certain examples, a purge gas may flow with the halogen-containing gas through the lower chamber of the reactor, e.g., the purge gas 34 (shown in FIG. 4), as shown with box 550.

It is contemplated that the halogen containing gas may etch an upper surface of the substrate to control thickness of a silicon layer deposited onto the upper surface of the substrate, e.g., control thickness of the silicon layer 18 (shown in FIG. 1) within the peripheral portion 40 (shown in FIG. 5), as shown in with box 580. In the certain examples the method 500 may include etching silicon on a lower surface of the substrate, e.g., the lower surface 14 (shown in FIG. 1), as shown with box 570. In accordance with certain examples, the method 500 includes etching a deposited film on at least one wall bounding the lower chamber of the reactor, e.g., the walls 132 (shown in FIG. 1) of the lower chamber 120 (shown in FIG. 1), as shown with box 560. Etching the upper surface of the silicon layer may include controlling thickness of the silicon layer within a peripheral portion of the silicon layer, e.g., the peripheral portion 40 (shown in FIG. 5), as shown with box 582. Etching the upper surface of the silicon layer may include tuning a thickness profile of the silicon layer within the peripheral portion of the of the silicon layer, as shown with box 584.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

### ELEMENT LISTING

10 Substrate
12 Upper Surface
14 Lower Surface
16 Edge or Bevel
18 Silicon Layer
20 Silicon-Containing Gas
22 Silicon Nodule
24 Silicon Film
26 Silicon Film
28 Halogen-Containing Gas
30 Dopant Gas
32 Carrier Gas
34 Purge Gas
36 Flow Arrow
38 Flow Arrow
40 Flow Arrow
42 Peripheral Portion
100 Semiconductor Processing Device
102 Reactor
104 Divider
106 Substrate Holder
108 Silicon-Containing Gas Source
110 Halogen-Containing Gas Source
112 Ceramic Material
114 Transmissive Material
116 Interior
118 Upper Chamber
120 Lower Chamber
122 Divider Aperture
124 One or More Lamp or Lamp Array
126 Rotation Axis
128 Substrate Holder Drive
130 One or More Lifter Pin
132 Walls
134 Gate Valve
136 Substrate Handler
138 Arm/End Effector
140 Dopant Gas Source
142 Carrier Gas Source
144 Purge Gas Source
146 Aperture
148 Gap
200 Semiconductor Processing Device
202 Remote Plasma Unit
300 Semiconductor Processing Device
302 Controller
304 Silicon-Containing Mass Flow Device
306 Halogen-Containing Gas Mass Flow Device
308 Device Interface
310 User Interface
312 Processor
314 Memory
316 Program Modules
400 Semiconductor Processing Device
402 First Halogen-Containing Gas Device Mass Flow Device
404 First Halogen-Containing Gas Conduit
406 Second Halogen-Containing Gas Mass Flow Device
408 Second Halogen-Containing Gas Conduit
410 Controller
500 Method
510 Box
520 Box
530 Box
540 Box
550 Box
560 Box
570 Box
580 Box

We claim:

1. A semiconductor processing system, comprising:
a reactor having an upper chamber and a lower chamber, the reactor configured to support therein a substrate with an upper surface and an opposite lower surface;
a silicon-containing gas source connected to the upper chamber of the reactor and configured to provide a silicon-containing gas to the reactor;
a halogen-containing gas source connected to the lower chamber of the reactor and configured to provide a halogen-containing gas to the reactor; and
a controller operatively connected to the semiconductor processing system and responsive to instructions recorded on a non-transitory memory to:
position the substrate within the upper chamber of the reactor;
flow the silicon-containing gas through the upper chamber of the reactor to deposit a layer of the upper surface of the substrate; and
flow the halogen-containing gas through the lower chamber to etch a deposited film on at least one wall bounding the lower chamber of the reactor while flowing the silicon-containing gas through the upper chamber of the reactor.

2. The semiconductor processing system of claim 1, wherein the instructions further cause the controller to etch the upper surface of the substrate with the halogen-containing gas to control thickness of a layer deposited onto a periphery of the upper surface of the substrate.

3. The semiconductor processing system of claim 1, wherein the halogen-containing gas source is connected to the upper chamber and the lower chamber of the reactor.

4. The semiconductor processing system of claim 1, further comprising a purge gas source connected to the lower chamber of the reactor to flow a purge gas flow through the lower chamber of the reactor with the flow of halogen-containing gas through the lower chamber of the reactor.

5. The semiconductor processing system of claim 1, further comprising:
a first mass flow controller (MFC) connecting the halogen-containing gas source to the upper chamber of the reactor to flow the halogen-containing gas through the upper chamber of the reactor as a carrier gas for the flow of silicon-containing gas; and
a second MFC connecting the halogen-containing gas source to the lower chamber of the reactor to flow the halogen-containing gas through the lower chamber of the reactor to etch at least one interior surface and/or structure within the reactor.

6. A semiconductor processing system, comprising:
a reactor having a divider separating an upper chamber and a lower chamber, the reactor configured to support therein a substrate with an upper surface and a lower surface that is opposite the upper surface;
a first inlet disposed in the upper chamber of the reactor;
a second inlet disposed in the lower chamber of the reactor;
a silicon-containing gas source connected to the first inlet in the upper chamber of the reactor and configured to provide a silicon-containing gas to the reactor; and
a halogen-containing gas source connected to the second inlet in the lower chamber of the reactor and configured to provide a halogen-containing gas to the reactor.

7. The semiconductor processing system of claim 6, wherein the first inlet is spaced apart vertically from the second inlet.

8. The semiconductor processing system of claim 7, wherein the divider is disposed vertically between the first inlet and the second inlet.

9. The semiconductor processing system of claim 6, wherein:
the reactor comprises a sidewall,
the divider extends inward from the sidewall,
the first inlet is disposed through the sidewall and above the divider, and
the second inlet is disposed through the sidewall and below the divider.

10. The semiconductor processing system of claim 9, further comprising a third inlet disposed through the sidewall and below the divider.

11. The semiconductor processing system of claim 10, further comprising a purge gas source connected to the third inlet.

12. The semiconductor processing system of claim 6, further comprising a substrate holder supported within an interior of the reactor and configured to support therein the substrate, wherein the divider defines a divider aperture therethrough, the divider aperture providing fluid communication between the upper chamber and the lower chamber.

13. The semiconductor processing system of claim 12, wherein the substrate holder is configured to be positioned within the divider aperture during operation of the semiconductor processing system.

14. The semiconductor processing system of claim 12, further comprising a substrate holder drive operably coupled to the substrate holder, wherein the substrate holder drive is configured to displace the substrate between a first position and a second position along a rotation axis for loading the substrate into the reactor.

15. The semiconductor processing system of claim 14, wherein the substrate holder drive is configured to rotate the substrate holder about the rotation axis.

16. The semiconductor processing system of claim 12, further comprising an operational configuration, wherein in the operational configuration:
the substrate holder is disposed within the divider aperture;
an outer edge of the substrate holder is spaced apart laterally from an inner edge of the divider aperture defining a gap therebetween, and
the upper chamber is in fluid communication with the lower chamber through the gap.

17. The semiconductor processing system of claim 16, wherein:
the substrate holder further comprises an aperture extending therethrough, and
in the operational configuration, the aperture is configured to fluidly couple the lower chamber of the reactor with the lower surface of the substrate.

18. The semiconductor processing system of claim 6, further comprising a controller operatively connected to the semiconductor processing system and responsive to instructions recorded on a non-transitory memory to:
position the substrate within the upper chamber of the reactor;
flow the silicon-containing gas from the silicon-containing gas source out the first inlet disposed in the upper chamber of the reactor, and through the upper chamber of the reactor to deposit a layer of the upper surface of the substrate; and
flow the halogen-containing gas from the halogen-containing gas source out the second inlet in the lower chamber of the reactor, and through the upper chamber of the reactor to etch a deposited film on at least one wall bounding the lower chamber of the reactor while flowing the silicon-containing gas through the upper chamber of the reactor.

19. The semiconductor processing system of claim 18, wherein the instructions further cause the controller to etch the upper surface of the substrate with the halogen-containing gas to control thickness of a layer deposited onto a periphery of the upper surface of the substrate.

20. The semiconductor processing system of claim 18, wherein the halogen-containing gas source is connected to the upper chamber and the lower chamber of the reactor.
